(19) United States
(12) Patent Application Publication
(10) Pub. No.: US 2025/0373233 A1
(43) Pub. Date: Dec. 4, 2025

(54) HIGH-SPEED AND HIGH-CONSISTENCY FLIP-FLOP CIRCUITS

(71) Applicant: Micron Technology, Inc., Boise, ID (US)

(72) Inventors: Brian W. Huber, Allen, TX (US); Eric A. Becker, Boise, ID (US)

(73) Assignee: Micron Technology, Inc., Boise, ID (US)

(21) Appl. No.: 19/202,278

(22) Filed: May 8, 2025

Related U.S. Application Data
(60) Provisional application No. 63/654,395, filed on May 31, 2024.

(51) Int. Cl. H03K 3/037; G11C 7/22

(52) U.S. Cl. CPC H03K 3/0372; G11C 7/222

(57) ABSTRACT

A flip-flop circuit may be used to latch data responsive to an edge of a clock signal. An example flip-flop circuit includes a first latch which latches a value of the data when the clock is at a level, a NAND gate coupled to the output of the first latch and the clock signal, and a second latch which is set to provide a high logical output based on the output of the NAND gate. In this way, the second latch is set on a next rising edge of the clock signal. The flip-flop circuit may be faster and more consistent than a conventional flip-flop. In an example application, the flip-flop circuit may be used as part of a synchronizer circuit in a memory device for external write leveling.

### CROSS REFERENCE TO RELATED APPLICATION(S)

This application claims the benefit under 35 U.S.C. 119 of the earlier filing date of U.S. Provisional Application No. 63/654,395 filed May 31, 2024, the entire contents of which are hereby incorporated by reference in its entirety, for any purpose.

### BACKGROUND OF THE INVENTION

There are a variety of applications where it is useful to store information using electronic circuits. For example, a latch circuit may have two states, representing a logical high and a logical low. There are a variety of latch circuits, which may have different configurations and operations based on their desired use. For example, a gated latch circuit may only change the state of its output when an enable signal is at a certain level, either high or low depending on the type of latch. For this reason latch circuits may generally be referred to as ‘level-set’ since they change state based on the level of one or more inputs. A flip-flop circuit may be used to store a binary bit of information based on the state of an input based on an edge of the enable signal. For example, on a rising edge of the clock signal, the state of the input may be latched in the flip-flop circuit, changing a state of the circuit such that the output matches the latched value. A flip-flop circuit may thus be referred to as edge triggered. It may be important to optimize both the speed at which the flip-flop circuit is able to change states as well as the consistency of the behavior of the flip-flop.

An example application which uses flip-flop circuits includes memory devices such as dynamic random access memory (DRAM). A memory device may include a number of flip-flop circuits for various operations of the memory. For example, during write leveling, to align an internal clock signal with a data strobe, mock commands are passed through a shifter made of flip-flop circuits, clocked with a mock clock signal, and measurements are made about the alignment of those signals compared to the data strobe. It may be useful to have a flip-flop circuit with high consistency to help ensure the accuracy of the alignment.

### BRIEF DESCRIPTION OF DRAWINGS

FIG. 1 is a schematic diagram of a flip-flop circuit according to some embodiments of the present disclosure.

FIGS. 2A-2G are schematic diagrams of example variations of flip-flop circuits according to some embodiments of the present disclosure.

FIG. 3 is a timing diagram of the operation of an example flip-flop according to some embodiments of the present disclosure.

FIGS. 4A-4B are schematic diagrams of gated extend latches according to some embodiments of the present disclosure.

FIGS. 5A-5B are schematic diagrams of NAND gates according to some embodiments of the present disclosure.

FIGS. 6A-6B are schematic diagrams of gated latch circuits according to some embodiments of the present disclosure.

FIG. 7 is a graph of the performance of an example flip-flop circuit according to some embodiments the present disclosure compared to the performance of a conventional flip-flop circuit.

FIG. 8 is a pair of graphs showing the consistency of an example flip-flop circuit according to some embodiments of the present disclosure compared to a conventional flip-flop circuit.

FIG. 9 is a flow chart of a method of operating a flip-flop circuit according to some embodiments of the present disclosure.

FIG. 10 is a block diagram of a semiconductor device according to at least one embodiment of the disclosure.

FIG. 11 is a schematic diagram of a command shifter according to some embodiments of the present disclosure.

FIG. 12 is a schematic diagram of a synchronizer circuit according to some embodiments of the present disclosure.

### DETAILED DESCRIPTION OF THE INVENTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A flip-flop circuit is a form of bistable circuit. The flip-flop circuit includes a number of terminals, such as a data terminal (D), a clock terminal CLK, and an output terminal (Q). Responsive to an active edge of a clock signal applied to the clock terminal, either the rising edge, the falling edge, or both depending on the configuration, the flip-flop circuit captures the state of the signal on the data terminal and provides that latched state as the output along the output terminal. For example, if the rising edge is the active edge, then responsive to a rising edge of the clock signal on the clock terminal the state of the data signal on the data terminal may be latched. This latched level may be provided as the output signal Q along the output terminal until the next rising edge of the clock signal. The flip-flop circuit may also include one or more other terminals such as set terminals(S), reset terminals (R), multiple data inputs and multiplexer terminals (MUX) to select between those inputs, and so forth. Any of the terminals may be active at a logical high level or active at a logical low level, depending on the configuration of the flip-flop circuit.

A flip-flop circuit may be formed by combining two gate enabled latch circuits. Both of the gate enabled latches have a data terminal D, a clock terminal Q, and an enable terminal LAT. Responsive to a level of the enable signal on the enable terminal, either a logical high or a logical low depending on the configuration, the latch circuit sets the value of the output signal on the output terminal to the value of the data signal on the data terminal for as long as the enable signal is at the active level. For example, as long as the enable signal is active, the output signal may generally be expected to match the input signal. A conventional flip flop circuit may be formed by coupling two gate enabled latch circuits in series, with the output terminal of the first latch coupled to the input terminal of the second, and then coupling an enable terminal of the first latch to a clock signal through an inverter and coupling the enable terminal of the second latch directly to the clock signal.

Flip-flop circuits may be characterized by various properties such as the time it takes to latch the state of the data signal. Responsive to the active edge of the clock signal the flip-flop circuit sets the output to the state of the input, however there may be a non-zero amount of delay between the rising edge and the output being set. For example, the flip-flop circuit may have a metastable state between the logical high and low outputs. Reducing that metastability may increase the speed of the flip-flop. Similarly, the flip-flop circuit may also have variability, for example due to process/voltage/temperature (PVT) variations. This variability may alter the timing characteristics of the flip-flop, such as a set time, hold time, or both of the flip-flop circuit. It may be useful to increase the speed at which the flip-flop circuit operates, increase the consistency of the flip-flop circuit, or both.

The present disclosure is drawn to apparatuses, systems, and methods for high-speed and high-consistency flip-flop circuits. An example flip-flop circuit of the present disclosure includes a reset terminal, a clock terminal, a data terminal, an output terminal, a NAND gate, and two gate enabled latch circuits. The first gate enabled latch circuit has its enable terminal coupled to the clock terminal and its output coupled to an input of the NAND gate. The other terminal of the NAND circuit is coupled to the clock terminal. The output of the NAND gate is coupled to a set terminal of the second gate enabled latch circuit. The first gate enabled latch has its input coupled to the data terminal and the second gate enabled latch has its input coupled to a ground voltage. In this way, the number of logic gates between the input and the outputs may be reduced compared to a conventional arrangement, which may increase the speed of the flip-flop circuit.

The flip-flop circuit of the present disclosure may also be modified into one or more different configurations, such as self-reset, independent reset of each gate enabled latch, multiplexer behavior, set/reset state dependence, or others. Some example applications may call for additional tuning of one or more components of the flip-flop circuit. For example, write leveling may be particularly sensitive to the consistency of the flip-flop circuit, so variations of the first gated latch circuit, second gated latch circuit, NAND gate, or combinations thereof may be used to optimize the consistency.

FIG. 1 is a schematic diagram of a flip-flop circuit according to some embodiments of the present disclosure. The flip-flop circuit 100 includes a data terminal D, a clock terminal CLK, a reset terminal Rf, a first output terminal Q, and a second output terminal Qh. The flip-flop circuit 100 includes a first gate enabled latch circuit 102, a NAND logic gate 104, and a second gate enabled latch circuit 106. The first gate enabled latch circuit 102 has an input terminal D, an output terminal Q, an enable terminal LAT, and a reset terminal Rf. The second gate enabled latch circuit 106 has an input terminal D, an output terminal Q, an enable terminal LAT, and a set terminal Sf.

As used herein which are marked with a lower case ‘f’ are the logical inverse of the signal which does not have the lower case f. In the example of FIG. 1, the reset terminal Rf is marked to indicate that it is the logical inverse of a reset signal R. Accordingly, the reset signal Rf may be active at a low logical level. Similarly, the convention may be used on the terminal of the flip-flop circuit 100 and latch circuits 102 and 106 to indicate if the terminal is active high or active low. Thus, the reset terminal Rf of flip-flop circuit 100 and the first latch circuit 102 are active low and the set terminal Sf of the second gate terminal is active low. For example, when the signal Rf is at a logical low, the first latch circuit 102 may be reset. Terminals and signals which do not have the suffix ‘f’ or which have the suffix ‘t’, will generally be treated as being active at a logical high. The exception to this is the enable signals LAT of the latches 102 and 106, which are enabled when the coupled signal is a logical low.

As used herein, it will generally be assumed that different voltages are used by the circuits to represent a logical high and a logical low. For example, a ground voltage such as VSS may be used to represent a logical low and a system voltage which is higher than the ground voltage, such as VDD or VPERI, may be used to represent a logical high. Other conventions may be used in other example implementations.

The reset terminal of the flip-flop 100 is coupled to the reset terminal of the first latch 102 and the enable terminal of the second latch 106. The data terminal is coupled to the input terminal of the first latch 102. The clock terminal is coupled to the enable terminal of the first latch 102 and to a first input terminal of the NAND gate 104. The output of the first latch is coupled to the second output terminal Qh of the flip-flop circuit 100 and to the second input terminal of the NAND gate 104. The output of the NAND gate 104 is coupled to a set terminal of the second latch 106. The input terminal of the second latch 106 is coupled to a ground voltage representing a logical low. The output of the second latch 106 is coupled to the first output terminal Q of the flip-flop circuit.

The reset terminal Rf of the flip-flop circuit 100 provides a reset signal Rf to the reset terminal of the first latch 102 and to the enable terminal of the second latch 106. Accordingly, if the reset signal is active and thus Rf is a logical low, then the first latch 102 will be reset and provide a logical low as its output and the second latch 106 will be disabled. If the reset signal is inactive, and thus Rf is a logical high, then the first latch 102 will not be reset and the second latch 106 will be enabled, causing it to pass the value of the input terminal D as the output, unless its set terminal is activated. Since the input terminal is coupled to a ground voltage representing a logical low, when the reset signal is inactive, the first output terminal Q will provide a logical low, unless the output of the NAND gate 104 is a logical low, which will activate the set terminal of the second latch 106, causing the second latch circuit 106 to provide a logical high as the output Q.

The NAND gate 104 will provide a logical low output, activating the set terminal of the second latch 106, only when both inputs of the NAND gate 104 are at a logical high. The first latch 102 will provide a logical high output when the input terminal D of the flip-flop 102 is a logical high, the reset signal is inactive, and the clock signal on the clock terminal CLK of the flip-flop 100 is a logical low, causing the first latch 102 to pass the value of D. When the clock signal CLK becomes high again, then assuming reset Rf is inactive (e.g., a logical high), then the latch 102 will still provide D at a logical high and both inputs of the NAND gate 104 will be a logical high. This will cause the output of the NAND gate 104 to be a logical low, which will set the second latch 106 and the output of the flip-flop 100 will become logical high. In this way the output of the NAND gate 104 will change on a next rising edge after the data D is captured in the latch 102. Since the set terminal Sf of the second latch is used to set the overall output of the flip-flop circuit 100 to a logical high, then the output will remain at a logical high until the reset signal Rf becomes active (e.g., when Rf is a low logical level). When reset Rf is a logical low, the latch 106 will be enabled, and will pass the input VSS, which represents a logical low. In this way, if subsequently the input D is a logical high, then that value will be captured on a rising edge of the clock terminal CLK and will remain even if the input D becomes a logical low while the clock is still high.

Accordingly, the flip-flop circuit 100 may be tuned to provide the maximum speed when capturing a logical high on the data terminal D responsive to a rising edge of the clock signal CLK. When the clock signal becomes active, there is a two gate delay from the clock signal to the output terminal Q. In particular, there is one gate delay from the NAND gate 104, and one gate delay from the second latch circuit 106 since the set terminal is used. In contrast, there is a four gate delay from the clock terminal to the second output Qh, since the first latch circuit 102 provides four gates of delay in this path.

The second output terminal Qh is coupled to the output of the first latch circuit 102. Accordingly, the second output terminal Qh may provide a level dependent output that matches the input terminal value as long as CLK is at a logical low and as long as Rf is inactive. In some embodiments, the second output terminal Qh may be omitted and the output of the first latch 102 may be a signal internal to the flip-flop circuit 100.

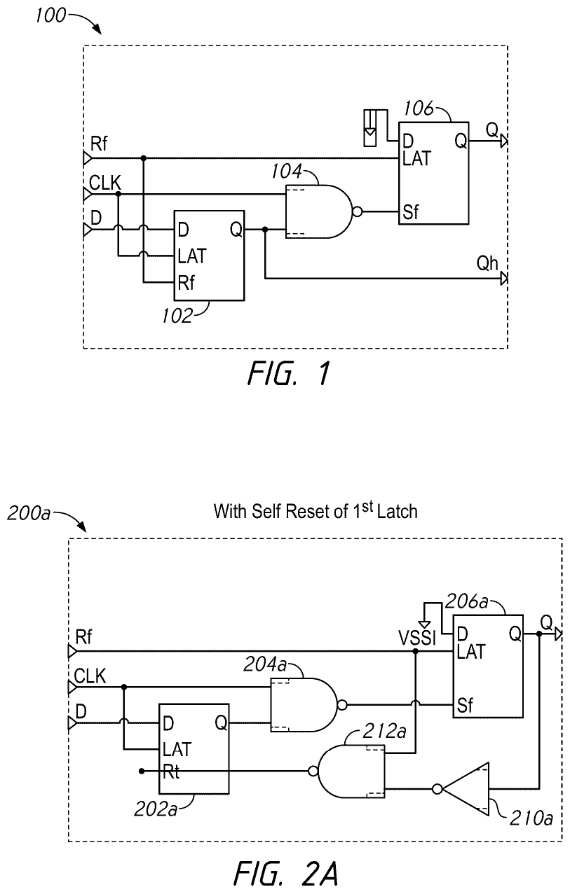

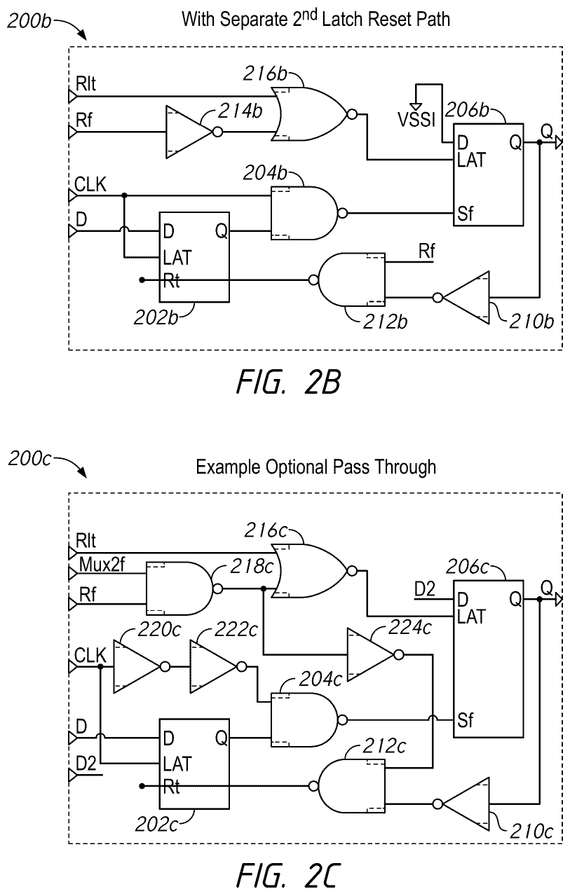

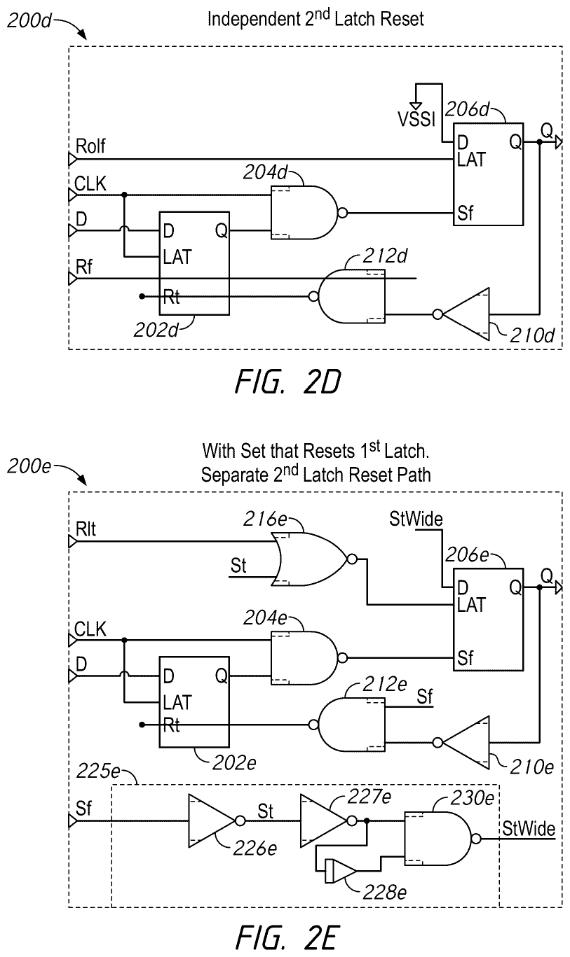

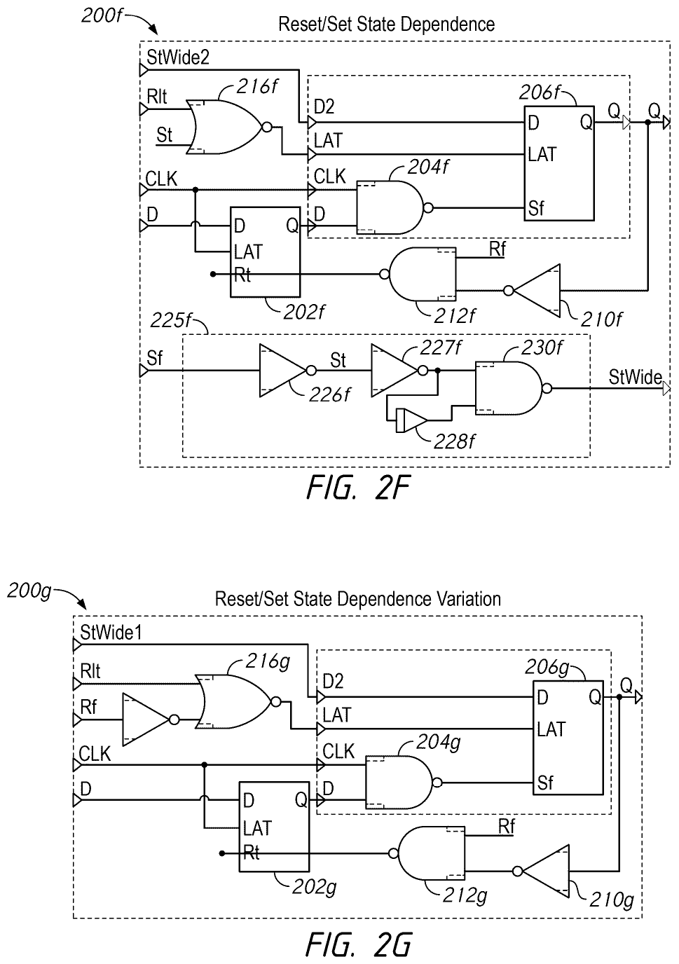

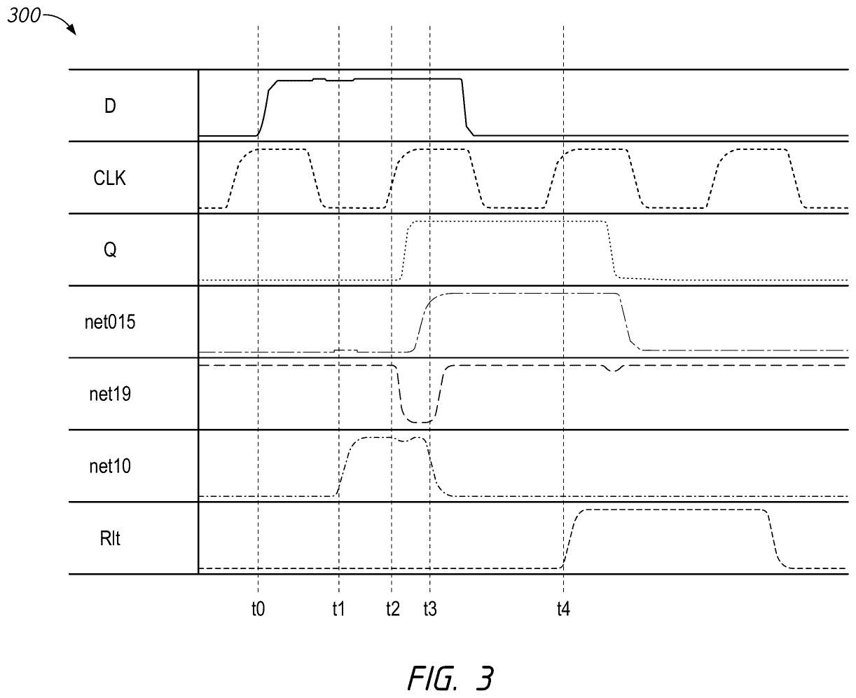

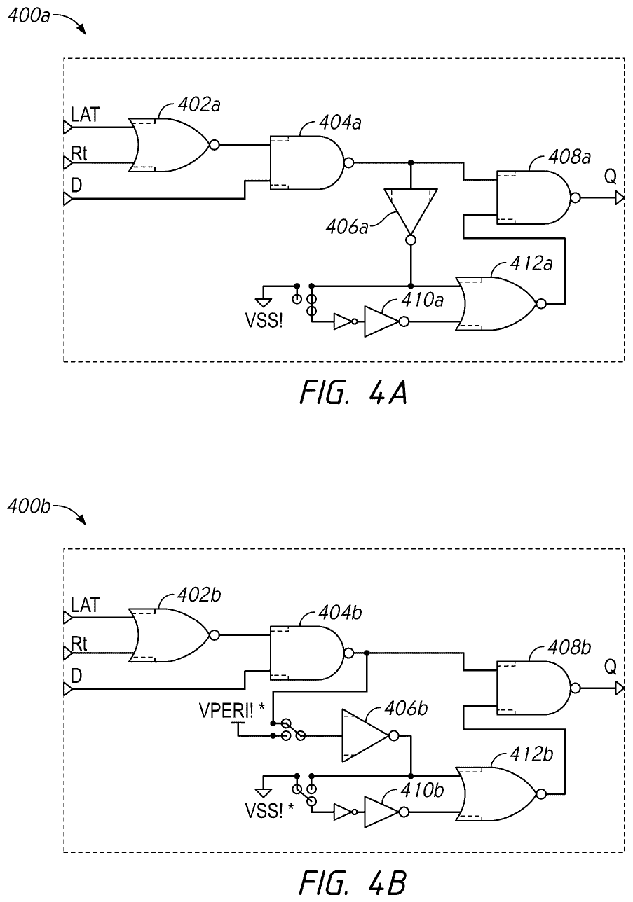

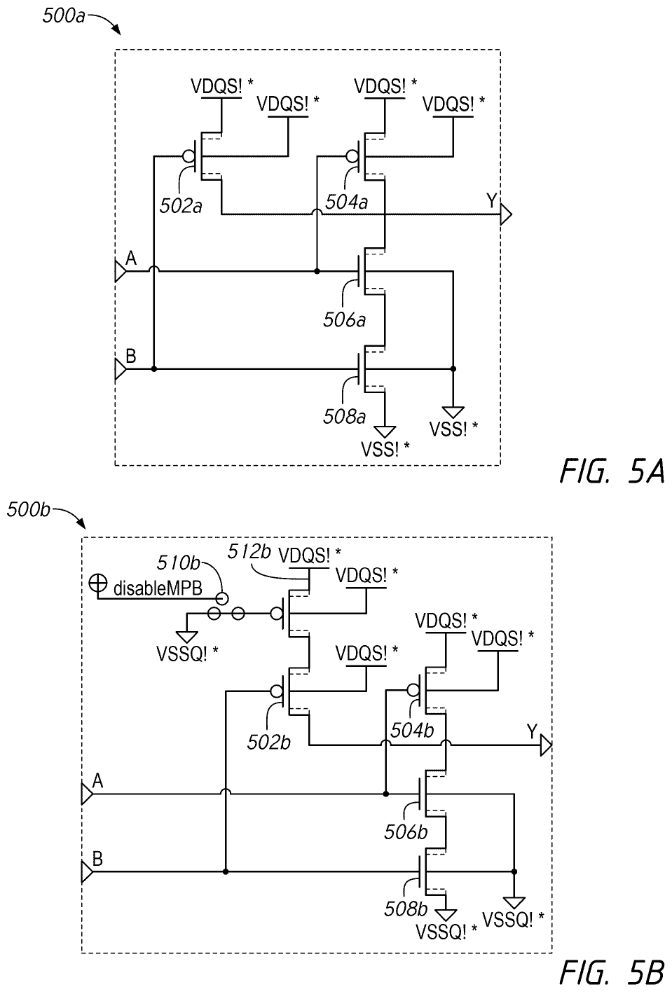

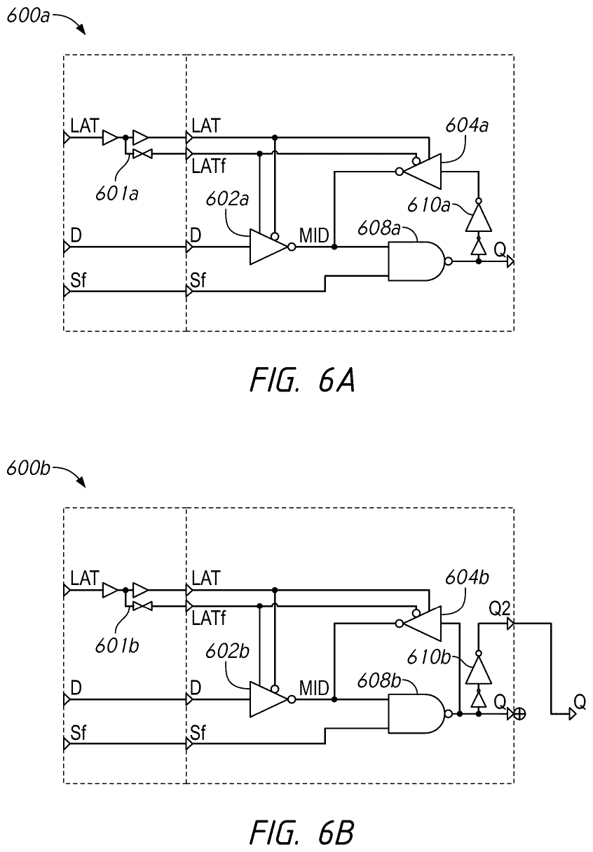

In some embodiments, the first latch 102, the NAND gate 104, and the latch circuit 106 may be conventional circuits, such as conventional latch circuits (or conventional flip-flop circuits used as latches) and conventional NAND gates. In some embodiments, one or more of the first latch 102, NAND gate 104, and second latch circuit 106 may be tuned or otherwise altered to give certain performance characteristics. FIGS. 4A-4B describe example gated extend circuits which may be used as the first latch 102 in some embodiments. FIGS. 5A-5B describe example NAND gates which may be used as the NAND gate 104 in some embodiments. FIGS. 6A-6B describe example latches which may be used as the second latch 106 in some embodiments. Any of these alternate components may be used in any combination. For example, some example embodiments may use one of the NAND gates of FIGS. 5A-5B but use conventional latches as the first and second latch. Some example embodiments may use one of the gated extend circuits of FIGS. 4A-4B as the first latch 102 and one of the NAND gates of FIGS. 5A-5B as the NAND gate. Similarly, any of the flip-flop variations described in FIGS. 2A-2G may use any combination of conventional components or the circuits described in FIGS. 4A-6B.

FIGS. 2A-2G are schematic diagrams of example variations of flip-flop circuits according to some embodiments of the present disclosure. The flip-flop circuits 200a-g are different variations of the flip-flop circuit 100 of FIG. 1. Each of the different flip-flop circuits 200a-g represents a different example configuration that may exhibit different behavior. The different configurations may be useful in different example applications. Each of the variations 200a-g include components similar to the flip-flop 100 of FIG. 1. For example, each of the variations 200a-g includes a first gated latch circuit 202, a NAND gate 204, and a second gated latch circuit 206. For the sake of brevity, signals and operations already described with respect to FIG. 1 will not be repeated again with respect to FIG. 2. Similarly, some of the variations may include similar components and operations to each other. Details explained with respect to one of the variations 200a-g may not be repeated for all of the variations 200a-g. Similar numbering will generally be used to denote analogous components between different variations. For example, each of the variations 200a-g may have their own inverter 210a-g and second NAND gate 212a-g as part of a self-reset path. However, the self-reset path may not be explained in detail with respect to each of the variations.

FIG. 2A shows a flip-flop circuit 200a is configured for self-reset of the first latch 202a. The flip-flop circuit 200a includes an inverter circuit 210a and a second NAND gate 212a. The output of the second latch circuit 206a is coupled through the inverter circuit 210a to an input terminal of the second NAND gate 212a. The other input terminal of the second NAND gate 212a is coupled to the reset terminal Rf of the flip-flop circuit 200a. The output of the second NAND gate 212a is coupled to the reset terminal of the first latch circuit 202a. Unlike the flip-flop circuit 100 of FIG. 1, the reset terminal of the first latch circuit 202a is not coupled to the reset terminal Rf of the flip-flop circuit 200a except through the second NAND gate 212a. Also unlike the flip-flop circuit 100 of FIG. 1, the first latch 202a has an active high reset terminal Rt instead of an active low reset terminal. Accordingly, when the value on the reset terminal of the first latch 202a is a logical high, the first latch 202a will be reset and will provide a logical low as the output.

The second NAND gate 212a will reset the first latch 202a as long as either the reset terminal Rf is receiving a logical low or the output Q is a logical high, which the inverter 210a will make a logical low. When the first latch 202a is reset, the first latch 202a will provide a logical low until the enable signal CLK and the data signal D are both active again. While the first latch 202a provides a logical low, the first NAND gate 204a will provide a logical high, which will keep the set terminal of the second latch 206a from being set. If the output Q becomes a logical high, then this will cause the second NAND gate 212a to reset the first latch 202a. In this manner, the first latch 202a will be automatically reset after the output of the flip-flop 200a becomes a logical high.

FIG. 2B shows a flop-flop circuit 200b configured for self-reset of the first latch 202b and a separate reset path for the second latch 206b. The flip-flop circuit 200b includes a self-reset path including an inverter 210b and second NAND gate 212b. The flip-flop circuit 200b also includes a second inverter circuit 214b and a NOR gate 216b. The flip-flop circuit 200b also includes a second reset terminal Rlt, which is active high. The NOR gate 216b has input terminals coupled to the second reset terminal Rlt and through the second inverter circuit 214b to the first reset terminal Rf. The output of the NOR gate 216b is coupled to the enable terminal LAT of the second latch circuit 206b. If either enable signals are active, with Rlt active at a logical high or Rf active at a logical low, then the second latch 206b will be enabled. Once enabled, the second latch 206b will provide a logical low as the output Q. The input pin Rlt only affects the second latch 206b, while the input pin Rf affects both of the latches 206b and 202b.

FIG. 2C shows a flip-flop circuit 200c configured to allow a pass through mode based on a multiplexer signal. The flip-flip 200c includes a self-reset path including an inverter 210c and a second NAND gate 212c. Compared to the flip-flop circuit 200b, the flip-flop circuit 200c also includes a second data input D2 and a multiplexer input Mux2f. Instead of being coupled to a ground voltage, the input terminal of the second latch circuit 206c is coupled to the second data input D2. The clock signal CLK is coupled through two inverter circuits 220c and 222c in series to the input terminal of the first NAND gate 204c. The flip-flip circuit 200c includes a third NAND gate 218c which has input terminals coupled to Rf and Mux2f. The output of the third NAND gate 218c is coupled through an inverter 224c to an input of the second NAND gate 212c in the self-reset path. The NOR gate 216c has input terminals coupled to the second reset terminal R It and to the output of the NAND gate 218c.

When both Mux2f and Rf are inactive, at a logical high, the NAND gate 218c provides a logical low to the NOR gate 216c. If the second reset signal R It is also inactive, at a logical low, then the NOR gate 216c provides a logical high, which disables the second latch 206c. If either Mux2f or Rf is active (at a logical low) then the NAND gate 218c will provide a logical high. This will cause the NOR gate 216c to provide a logical low, which causes the second latch 206c to pass the second data input D2 and provide it as the output Q. In this manner, the flip-flop circuit 200c acts as a pass-through of the second data input D2 based on the settings of Mux2f, Rlt, and Rf. Assuming that the reset signals are in their inactive states, then Mux2f may be driven low to control whether D2 is passed or not. In addition, the state of Mux2f and Rf will affect the self-reset path. The output of the NAND gate 218c being a logical low will cause the inverter 224c to provide a logical high to the input terminal of the second NAND gate 212c along the self-reset path. Accordingly, when the output of the second latch 206c is a logical high or when the output of the third NAND gate 218c is a logical high, the second NAND gate 212c will reset the first latch 202c.

FIG. 2D shows a flip-flop circuit 200d with an independent reset of the second latch 206d. The flip-flop circuit 200d may generally be similar to the flip-flop circuit 200a, except that in the flip-flop circuit 200d, there is a first reset terminal Rf coupled to the second NAND gate 212d and a second reset terminal Rlof coupled to the enable terminal of the second latch 206d. Accordingly, the two reset signals may operate generally independent of each other, except indirectly through the second latch 206d. The second reset terminal Rlof directly controls whether the second latch 206d is enabled or not. When the signal Rlof is active, at a logical low, the second latch 206d is enabled and sets the output Q to a logical low. When the output Q is a logical high or when Rf is active at a logical low, the second NAND gate 212d will reset the first latch 202d.

FIG. 2E shows a flip-flop circuit 200e with set signal which resets the first latch 202e and a separate reset path for the second latch 206e. The flip-flop circuit 200e includes a set signal generator circuit 225e, which includes two inverter circuits 226e and 227e, a delay circuit 228e, and a NAND gate 230e. The flip-flop circuit 200e includes a reset terminal Rlt and a set terminal Sf. The set signal generator is coupled to the set signal Sf and generates an inverse set signal St and a set pulse StWide. The set signal Sf is coupled through the inverter 226e to generate the inverse set signal St. The inverse set signal St is coupled through a second inverter 227e and provided as an input to NAND gate 230e. The second inverter 227e is also coupled through delay circuit 228e to the second input of 230e. The NAND gate 230e provides the extended set signal StWide as its output. Accordingly, if the signal Sf goes from being inactive at a high logical level to active at a low logical level, the signal StWide will change to a high logical level, and the signal St will rise to a high logical level. When the signal Sf goes back to being inactive, St will go back to being a low logical level, but StWide will remain active for a period of time based on the length of the delay circuit 228e.

In the self-reset path, the second NAND gate 212e has an input coupled through the inverter 210e to the output Q and an input coupled to Sf. The second latch 206e has its input terminal coupled to StWide and its enable terminal coupled to the output of a NOR gate 216e. When the signal set Sf becomes active at a logical low, the output of the NAND gate 212e will become a logical high, which in turn will reset the first latch 202e. The signal Sf becoming active at a logical low will also cause St to become active at a logical high. This will drive the output of the NOR gate 216e to a logical low which will enable the second latch 206e. The second latch 206e will provide the signal StWide as the output.

FIG. 2F shows a flip-flop circuit with reset and set state dependence. The flip-flop circuit 200f may generally be similar to the flip flop circuit 200e, except that in the flip-flop circuit 200f, there is a second set signal input terminal for a signal StWide2, separate from the signal StWide provided by the NAND gate 230f. The signal StWide may be provided as an output of the flip-flop circuit 200f. This may be useful in arrangements where multiple flip-flops are coupled in series, such as in a shifter as it may allow a way to couple the reset/set state of the different flip-flops together. For example StWide2 may be provided by the output StWide of a different flip-flop in the series.

FIG. 2G is a flip-flop circuit with a variation of reset and set state dependence. The flip-flop 200g may be generally similar to the flip-flop 200b except that in the flip-flop circuit 200g, the input terminal of the second latch 206g is coupled to an extended set signal StWide1. The extended set signal may be provided by a set signal generator, such as in flip-flop circuit 200e and/or 200f. Similar to the flip-flop 200f, this may be useful in situations where multiple flip-flop circuits are coupled together. For example the set signal StWide1 may be generated by a different flip-flop circuit such as 200e or 200f.

FIG. 3 is a timing diagram of the operation of an example flip-flop according to some embodiments of the present disclosure. The timing diagram 300 represent the operation of an example flip-flop circuit. In particular, the timing diagram 300 represent the operation of the flip-flop circuit 200b of FIG. 2B. The timing diagram shows a number of traces, each of which represents the logical state of one or more signals of the flip-flop circuit as represented by a voltage. For the sake of clarity, the traces are shown scaled such that the voltages go from 0 (logical low) to 1 (logical high), however other voltages may be used in other example embodiments. Time is represented along the horizontal axis, and the same axis is used for each of the traces.

The timing diagram 300 shows traces for the flip-flop's data terminal D, clock terminal CLK, output terminal Q, and reset terminal Rlt. Also shown are intermediate signals within the flip-flop net015, net19, and net10. Referring back to FIG. 2B, net015 is the signal applied to the reset terminal Rt of the first latch 202b, net19 is the signal provided by the NAND gate 204b, and net10 is the output of the first latch 202b.

At an initial time to, the data terminal becomes active and rises from a logical low to a logical high. Since to is after the rising edge of the clock signal CLK, the output Q does not immediately change. However, at a first time t1, the value of the data terminal is latched in the first latch responsive the clock signal CLK being a logical low and activating the LAT terminal of the first latch. At a second time t2, the next rising edge of the clock signal CLK occurs. This causes the signal net19 from the NAND gate 204b to fall to a low level, which activates the set terminal of the second latch 206b. This in turn causes the output terminal Q to become active. In turn, this causes the self-reset signal net015 to rise to a logical high. This resets the first latch 202b, which at a time t3 causes the output of the first latch net10 to fall back to a logical low and this causes the set signal net19 to rise back to a logical high, inactivating the set terminal of the second latch 206b. The output Q remains at a logical high until it is reset at the time t4 when the reset signal R It becomes active.

FIGS. 4A-4B are schematic diagrams of gated extend circuits according to some embodiments of the present disclosure. The gated extend circuits or gated extend latch circuits 400a-b represent example gated latch circuits which may be used as the first latch circuit of a flip-flop circuit. For example, either of the gate extend circuits 400a-b may be used as the first latch 102 of FIG. 1, the first latch 202a-g of FIGS. 2a-g, or combinations thereof. The gated extend circuits 400a-b may be used in the flip-flop circuit some example embodiments. Conventional latches may be used in the flip-flop circuit in other example embodiments. The gated extend circuits 400a-b may represent optional first latch circuits which are tuned to a particular characteristic, such as increasing the speed and consistency of the overall flip-flop circuit. This may be useful for certain applications. For example, the gated extend circuits 400a or 400b may be particularly useful in write leveling, as described in more detail herein.

FIGS. 4A and 4B show gated extend circuits 400a and 400b respectively. The two latch circuits 400a and 400b may generally be similar to each other. The gated extend 400a-400b each of have an enable terminal LAT, a reset terminal Rt, a data terminal D, and an output terminal Q. The gated extend circuit 400a includes a NOR gate 402a, a NAND gate 404a, an inverter 406a, a second NAND gate 408a, a buffer circuit 410a, and a second NOR gate 412a. The first NOR gate 402a has input terminals coupled to LAT and Rt. The NAND gate 404a has input terminals coupled to the output of the NOR gate 402a and the data terminal D. The output of the NAND gate 404a is coupled to an input terminal of the NAND gate 408a and through the inverter 406a to an input terminal of the NOR gate 412a. That input terminal of the NOR gate 412a may also be coupled to a ground voltage through a switch when the output of the inverter 406a is a logical low. The other input of the NOR gate 412a is coupled through the buffer 410a to the output of the inverter 406a. The buffer 410a may be formed from two inverter circuits in series.

When either the enable signal LAT or the reset signal Rt are at a high logical level, the NOR gate 402a provides a low logical level as an output. When the NAND gate 404a receives a low logical level from either the NOR gate 402a or the data signal D, it provides a high logical level as the output. Accordingly, the output of the NAND gate 404a will only be a low logical level when D is active, and neither LAT nor Rt are active. If the output of the NAND 404a is at a high logical level, the inverter 406a will provide a logical low to the NOR gate 412a, and after a delay caused by the buffer 410a, both terminals of the NOR gate 412a will receive a logical low. This in turn causes the NOR gate 412a to provide a logical high. Since both inputs of the NAND gate 408a are a logical high, this causes the output Q to drop to a logical low. The buffer circuit 410a provides a delay time before the output Q drops to a logical low. If the output of the NAND gate 404a is a logical low, because D is a logical high and both Rt and LAT are a logical low, then the NAND gate 408a will provide a logical high as the output Q. Accordingly, assuming the latch circuit 400a is not being reset, the latch circuit will provide a logical high quickly once D is a logical high and a logical low on LAT is enabling the latch, but if either of those conditions change, there will be a delay before the latch circuit 400a switches to providing a logical low.

The gated extend circuit 400b of FIG. 4B may be generally similar to the gated extend circuit 400a of FIG. 4A. For the sake of brevity, components, signals and operations which are analogous to those already explained with respect to FIG. 4A will not be repeated again with respect to FIG. 4B. Similar reference numbers are used between FIGS. 4A and 4B to mark similar components. For example, the NOR gate 402b may generally correspond to the NOR gate 402a and so forth.

In the gated extend circuit 400b, the output of the NAND gate 404b is coupled to a switch that selects the output of the NAND gate 404b or a system voltage VPERI which represents a logical high to provide to the input of the inverter 406b. The output of the inverter 406b is provided to an input terminal of the NOR gate 412b and to a second switch which selects between providing a ground voltage VSS that represents a logical low or the output of the inverter 406b to the buffer 410b.

FIGS. 5A-5B are schematic diagrams of NAND gates according to some embodiments of the present disclosure. The NAND gates 500a-b represent example NAND gates which may be used as the NAND gate of a flip-flop circuit. For example, either of NAND gates 500a-b may be used as the NAND gate 104 of FIG. 1, 204a-g of FIGS. 2a-g, or combinations thereof. The NAND gates 500a-b may be used in the flip-flop circuit some example embodiments. Conventional NAND gates may be used in the flip-flop circuit in other example embodiments. The NAND gates 500a-b may represent optional NAND gates which are tuned to a particular characteristic, such as increasing the speed of the overall flip-flop circuit. This may be useful for certain applications. For example, the NAND gates 500a or 500b may be particularly useful in write leveling, as described in more detail herein.

FIGS. 5A and 5B show NAND gates 500a and 500b respectively. The two NAND gates 500a and 500b may be generally similar to each other. Both NAND gates 500a and 500b include two input terminals, here labelled A and B, and an output terminal here labelled Y. The second input terminal B is generally coupled to the clock terminal CLK of the flip-flop circuit, while the first input terminal A is generally coupled to the output of the first latch circuit (e.g., Q of 102 of FIG. 1, 202a-g of FIGS. 2A-G or combinations thereof). The output Y is generally coupled to a set terminal of the second latch circuit (e.g., Sf of 106 of FIG. 1, 206-a-g of FIGS. 2A-G, or combinations thereof).

FIG. 5A shows an example NAND gate 500a which includes four transistors 502a-508a. The first transistor 502a is a p-type transistor which has a source coupled to a supply voltage VDQS, a drain coupled to the output terminal Y and a gate coupled to the second input B. The second transistor 504a is a p-type transistor which has a source coupled to a system voltage VDQS, a drain coupled to the output Y, and a gate coupled to the first input terminal A. The third transistor 506a is an n-type transistor that has a drain coupled to the output Y, a gate coupled to the first input A, and a source coupled to the drain of the fourth transistor 508a. The fourth transistor 508a is an n-type transistor with a drain coupled to the source of the third transistor 506a, a gate coupled to the second input B, and a source coupled to a ground voltage VSS.

When the two inputs are both a logical high, then both the transistors 506a and 508a will be active, and both the transistors 502a and 502b will be inactive, which will cause the transistors 506a and 508a to couple the ground voltage VSS to the output Y. If A is a logical low, it will inactivate the transistor 506a and activate the transistor 504a. This will allow the output Y to be coupled to VDQS through the transistor 504a. If B is a logical low, it will inactivate the transistor 508a and activate the transistor 502a. This will allow the output Y to be coupled to VDQS through the transistor 502a.

In some embodiments, the transistor 502a may be removed. This may increase the speed at which the overall flip-flop circuit operates. In some embodiments, the transistor 502a may be relatively weak compared to the transistor 504a. For example the transistor 502a may be about ¼ the size of the transistor 504a.

The NAND gate 500b of FIG. 5B may be generally similar to the NAND gate 500a of FIG. 5A. For the sake of brevity, components, signals and operations which are analogous to those already explained with respect to FIG. 5A will not be repeated again with respect to FIG. 5B. Similar reference numbers are used between FIGS. 5A and 5B to mark similar components. For example, the transistor 502b may generally correspond to the transistor 502a and so forth.

In the NAND gate 500b, an extra switch 510b and transistor 512b are added compared to the NAND gate 500a. The transistor 512b is a p-type transistor coupled between the transistor 502b and the voltage VDQS. The gate of the transistor 512b is coupled to a switch 510b. The switch 510b receives a control signal disableMPB which selects whether or not to provide the group voltage VSS to the gate of the transistor 512b. This may allow whether or not to use the transistor 502b to be a selectable feature. If the signal disableMPB is inactive, then the ground voltage is coupled to the gate of transistor 512b, which in turn couples transistors 502b to VDQS. If the signal disableMPB is active, then the gate of transistor 512b is inactivated, and the transistor 502b is isolated from VDQS. Based on the setting of disableMPB, the operation of transistor 502b may be user selectable. Disabling the transistor 502b may increase the speed of the overall flip-flop but weaken the ‘pull-up’ effect when the input on the second terminal B (e.g., the CLK signal) is inactive.

FIGS. 6A-6B are schematic diagrams of gated latch circuits according to some embodiments of the present disclosure. The gated latch circuits 600a-b represent example gated latch circuits which may be used as the first latch circuit of a flip-flop circuit, the second latch circuit of a flip-flop circuit, or both. The example latch circuits 600a-b are shown with a set terminal Sf so that they could be used as the second latch circuits of a flip-flop. For example, either of gated latch circuits 600a-b may be used as the second latch 202 of FIG. 1, 202a-g of FIGS. 2a-g or combinations thereof. However, a modified version of the latch circuits 600a-b which have a reset terminal could be used as the first latch of the flip-flop instead or in addition in other example embodiments. The gated latch circuits 600a-b may be used in one or more of the flip-flop circuits described herein some example embodiments. Conventional gated latches may be used in the flip-flop circuit in other example embodiments. The gated latch circuits 600a-b may represent optional gated latch circuits which are tuned to a particular characteristic, such as increasing the speed of the overall flip-flop circuit. This may be useful for certain applications. For example, the gated latch circuits 600a or 600b may be particularly useful in write leveling, as described in more detail herein.

FIGS. 6A and 6B show latch circuits 600a and 600b respectively. The two latch circuits 600a and 600b may be generally similar to each other. Both latch circuits 600a and 600b include an enable terminal LAT, a data terminal D, and a set terminal Sf, and an output terminal Q. What inputs are coupled to those terminals may vary based on the type of flip-flop circuit. For example, in the configuration of the flip-flop 200a of FIG. 2A, the enable terminal LAT is coupled to a reset terminal Rf, the data input is coupled to a ground voltage VSS, and the set terminal is coupled to the output of the NAND gate (e.g., 204a).

FIG. 6A shows a latch circuit 600a. The latch circuit 600a includes an inverter and buffers 601a coupled to the enable terminal LAT. The inverter and buffer circuits 601a receive the signal latch and pass a buffered latch signal LAT which has the same state as the input and an inverted latch signal LATf which has the complimentary state to the input. The latch circuit 600a includes a first inverter circuit 602a which receives the input D and passes it as a signal MID. The first inverter circuit 602a may be a tri-state inverter. The first inverter 602a is enabled by the signal LATf being at a high logical level, which is when the input signal LAT is at a low logical level. The signal MID is provided as an input to a NAND gate 608a. The other input of the NAND gate 608a is coupled to the set terminal Sf. The output of the NAND gate 608a is the output Q. If either the input MID or the input Sf is a logical low, then the NAND gate 608a provides a logical high as the output Q. The output Q is feedback through buffer circuit 610a and inverter circuit 604a to the signal MID. The inverter circuit 604a may also be a tri-state inverter circuit, and is enabled by the signal LAT being at a high logical level. The buffer circuit 610a may be formed by coupling two inverters in series in some embodiments.

When the latch signal LAT receives a logical low, the value D is inverted into the signal MID. When the latch signal LAT receives a logical high the value Q is inverted into the signal MID. If D is a logical high, when LAT falls to a low, then MID will become a logical low, which causes Q to become a logical high. When LAT switches to a high, then the value Q will be inverted into a logical low on MID to maintain the state of the latch. If the signal Sf is received at a logical low (e.g., an active level for Sf) then the NAND gate 608a will set the output Q to a logical high even if LAT is at a logical high.

The latch 600b of FIG. 6B may be generally similar to the latch 600a of FIG. 6A. For the sake of brevity, components, signals and operations which are analogous to those already explained with respect to FIG. 6A will not be repeated again with respect to FIG. 6B. Similar reference numbers are used between FIGS. 6A and 6B to mark similar components. For example, the transistor 602b may generally correspond to the transistor 602a and so forth.

The latch 600b directly couples the output of the NAND gate 608b to the inverter circuit 604b, and the buffer circuit 610b is separately coupled to the output of the NAND circuit 608b to provide the output Q. In other words, in the latch 600a, the output Q is directly provided by the NAND gate 608a and the feedback is provided through a buffer 610a, but in the latch 600b the output Q is provided through the buffer 610b and the output of the NAND gate 608b is directly feedback through the inverter 604b. The inverter circuits 602b and 604b may be tri-state inverter circuits.

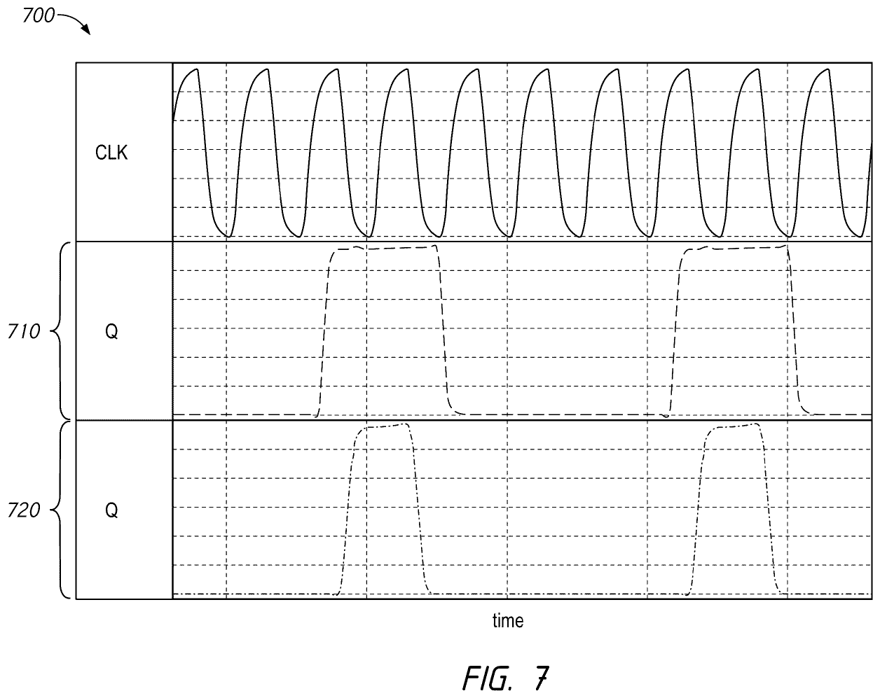

FIG. 7 is a graph of the performance of an example flip-flop circuit according to some embodiments of the present disclosure as trace 710 compared to the performance of a conventional flip-flop circuit as trace 720. The graph 700 represents the speed of an example flip-flop circuit compared to a conventional flip-flop circuit. In particular, the graph 700 represents the operation of the flip-flop circuit 100 of FIG. 1. Graph 700 shows the simulated performance of the flip-flop circuit 100 of FIG. 1 in trace 710 and the simulated performance of a conventional flip-flop circuit (e.g., two latches in series with enable terminals coupled in common to a clock signal, with one latch coupled through an inverter circuit to the clock signal) in trace 720. A clock signal is shown across the top. All three traces share a common time access. The two traces 710 and 720 show the output of the flip-flops Q.

An input terminal (not shown) is coupled to a data signal, which becomes a logical high. As may be seen, both flip-flops change their output to a logical high responsive to the next rising edge of the clock signal CLK. The data signal remains at a logical high for one clock cycle for trace 720 and longer than one clock signal for trace 710 in this example and then returns to a logical low, and both flip-flops capture that change. Other durations of the data signal being active may be used in other example operations. As may be seen by comparing the trace 710 to the trace 720, the flip-flop circuit 100 captures the change in data from logical low to logical high faster than a conventional flip-flop circuit. For example, the flip-flop circuit 100 of FIG. 1 may capture the change approximately 85 psec faster than the conventional flip-flop circuit.

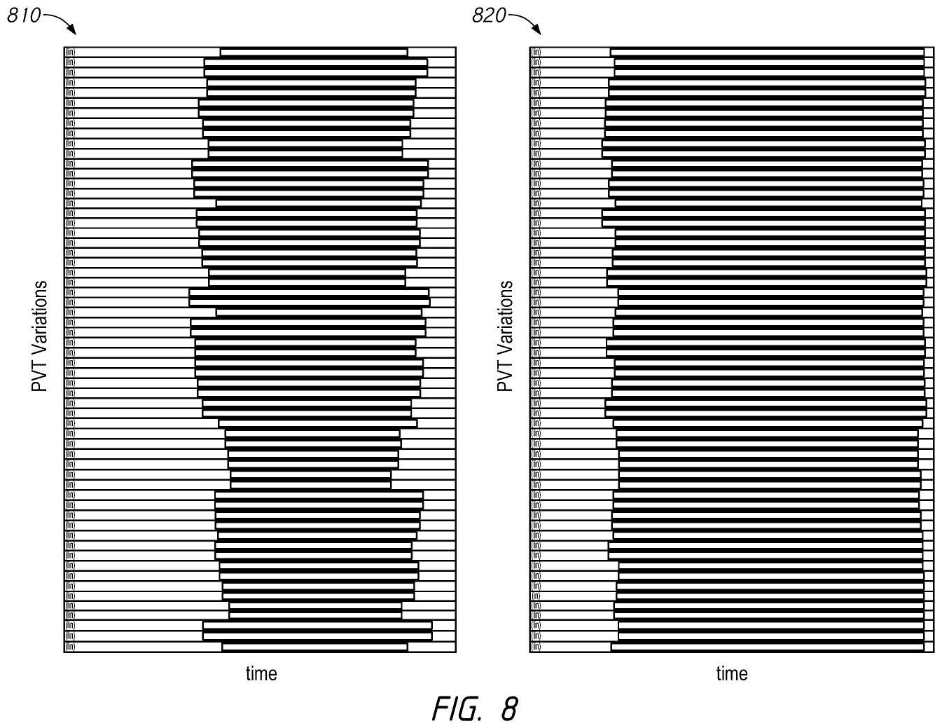

FIG. 8 is a pair of graphs showing the consistency of an example flip-flop circuit according to some embodiments of the present disclosure compared to a conventional flip-flop circuit. The graphs 810 and 820 show the set and hold time of two different flip-flop circuits compared across a variety of different simulated PVT variations. Both of the graphs 810 and 820 show time across the time axis. Both graphs 810 and 820 show a number of different traces, each showing a bar to show the performance of a flip-flop circuit with a simulated set of PVT characteristics. The graph 810 shows the simulated performance of a conventional flip-flop circuit. The graph 820 shows the performance of an example flip-flip circuit according to some embodiments of the present disclosure. For example, the graph 820 may represent the operation of the flip-flop circuit 100 of FIG. 1 using the gated extend circuit 400b of FIG. 4B as its first latch circuit 102.

The graph 810 shows a conventional latch with a setup time variation of about 21.4 psec and a hold time variation of about 22.5 psec. In comparison, the graph 820 shows the mentioned modified flip-flop circuit 100 of FIG. 1 with a setup time variation of about 5.0 psec and a hold time variation of about 9.1 psec. As may be seen, the flip-flop circuit of the present disclosure has improved consistency across a wide range of PVT conditions compared to conventional flip-flop circuits.

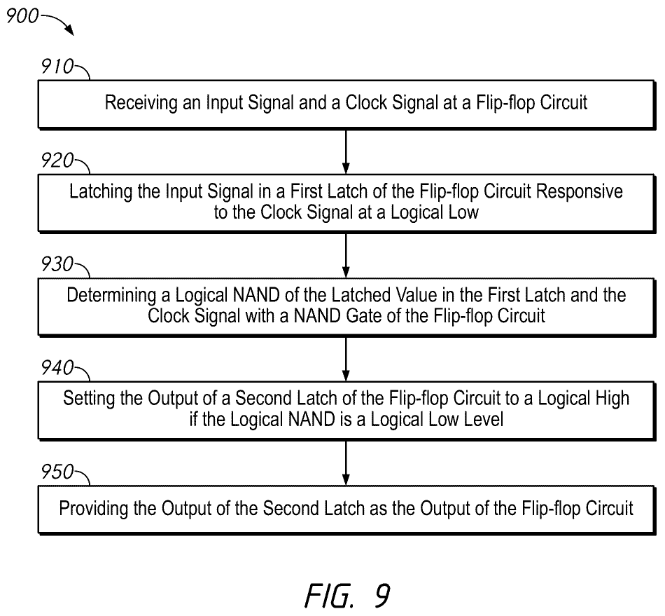

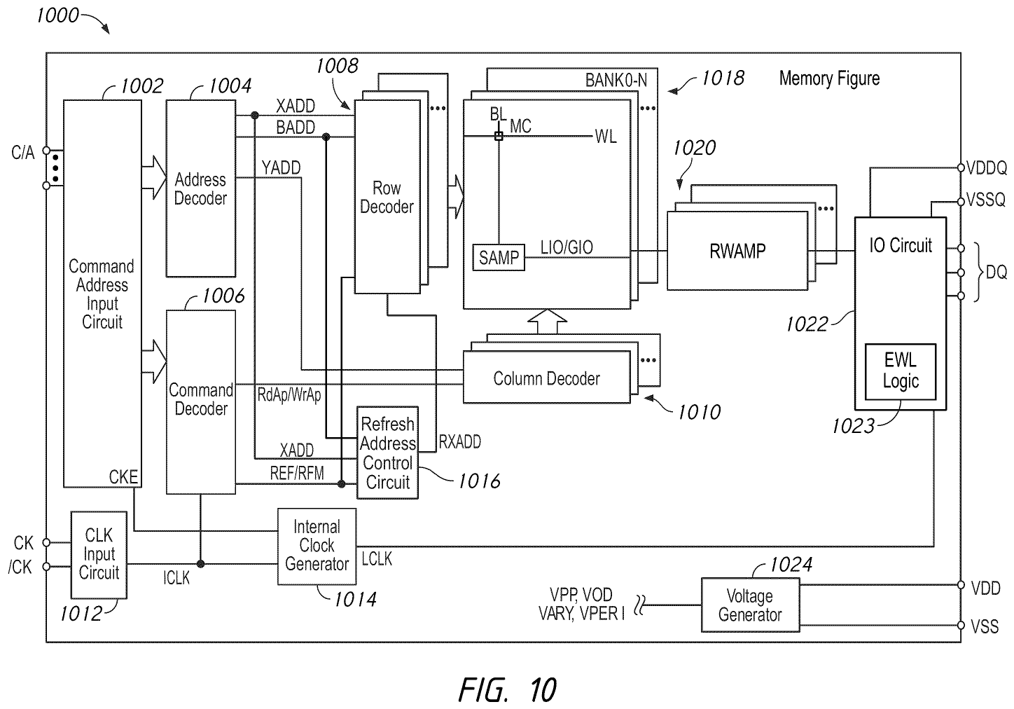

FIG. 9 is a flow chart of a method of operating a flip-flop circuit according to some embodiments of the present disclosure. The method 900 may be implemented by one or more of the flip-flop circuits described herein. For example, the method 900 may be implemented by the flip-flop circuit 100 of FIG. 1. The method 900 may also represent the operation of variations of the flip-flop circuit, such as circuits 200a-g of FIGS. 2A-G.

The method 900 may generally begin with box 910, which describes receiving an input signal (e.g., D) and a clock signal (e.g., CLK) at a flip-flop circuit. The input signal may be received at a data terminal and the clock signal may be received at a clock terminal of the flip-flop circuit. Box 910 is generally followed by box 920 which describes latching the input signal in a first latch (e.g., 102 of FIGS. 1 and/or 202a-g of FIG. 2) of the flip-flop circuit responsive to the clock signal being a logical low.

Box 920 may generally be followed by box 930, which describes determining a logical NAND of the latched value in the first latch and the clock signal with a NAND gate (e.g., 104 of FIGS. 1 and/or 204a-g of FIGS. 2a-g) of the flip-flop circuit. Box 930 may generally be followed by box 940, which describes setting the output of a second latch (e.g., 106 of FIGS. 1 and/or 206a-g of FIGS. 2a-g) of the flip-flop circuit to a logical high if the logical NAND is a logical low level. For example, the method 900 may include providing an output of the NAND gate to a set terminal of the second latch circuit. Box 940 may generally be followed by box 950, which describes providing the output (e.g., Q) of the second latch as the output of the flip-flop circuit. For example, the output of the second latch circuit may be coupled to an output terminal of the flip-flop circuit.

The method 900 may include resetting the second latch responsive to a reset signal. For example, the method 900 may include latching a voltage which represents a logical low in the second latch circuit responsive to a reset signal being active (e.g., at a logical low). In some embodiments, the method 900 may include resetting the first latch responsive to the reset signal. For example, the method 900 may include providing the reset signal to a reset terminal of the first latch circuit. In some embodiments, such as the circuits 200a-g of FIGS. 2a-g, the method 900 may include resetting the first latch circuit responsive to providing the output of the second latch at a logical high.

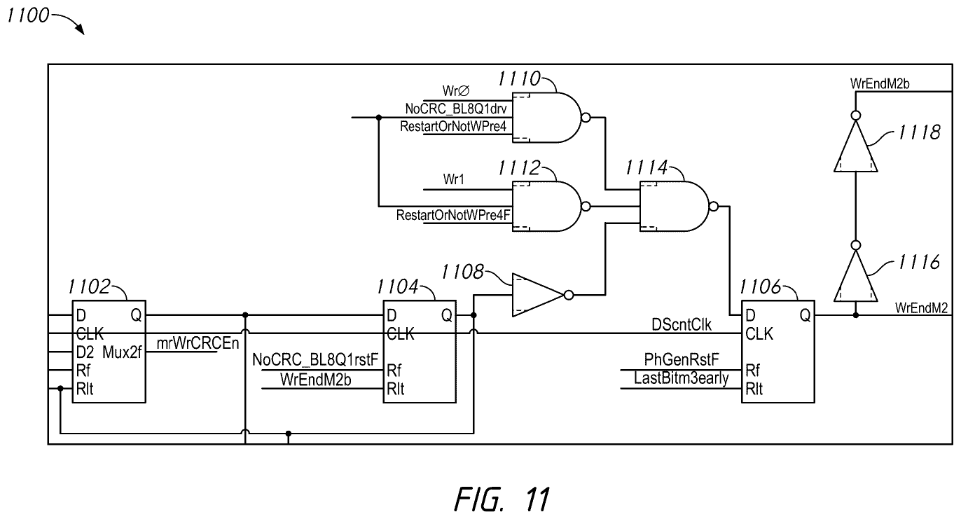

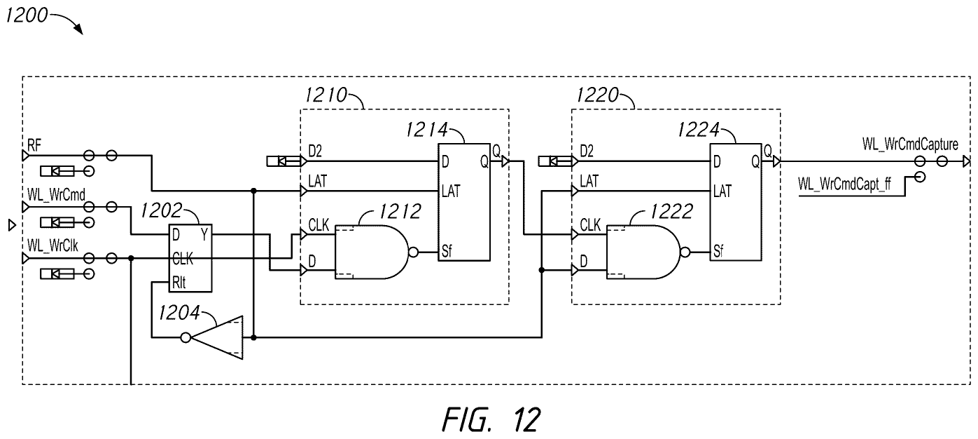

FIGS. 10-12 describe example applications for the flip-flop circuit 100 of FIG. 1, 200a-g of FIGS. 2A-G, or combinations thereof. A memory device may use a number of flip-flop circuits. Different configurations of the flip-flop circuit may be useful in different applications throughout the memory device. For example, the variations 200a-g may represent different versions of the flip-flop which are particularly useful in particular applications within a memory device. Two example embodiments within the memory are described herein. FIG. 11 describes an example circuit for write command timing, and FIG. 12 describes an example circuit for write leveling. Other applications for flip-flop circuits of the present disclosure may be used in other example embodiments.

FIG. 10 is a block diagram of a semiconductor device according to at least one embodiment of the disclosure. The semiconductor device 1000 may be a semiconductor memory device, such as a DRAM device integrated on a single semiconductor chip. The device 1000 may be operated by a controller (not shown). For example, the memory device 1000 receives various commands, data, signals, and voltages from the controller.

The semiconductor device 1000 includes a memory array 1018. The memory array 1018 is shown as including a plurality of memory banks. In the embodiment of FIG. 1, the memory array 1018 is shown as including N+1 memory banks BANK0-BANKN. For example, there may be four, eight, or sixteen banks. More or fewer banks may be used in other example embodiments. Each memory bank includes a plurality of word lines WL (rows), a plurality of bit lines BL (columns), and a plurality of memory cells MC arranged at intersections of the plurality of word lines WL and the plurality of bit lines BL. Each memory cell stores information. For example, the memory cell may be a capacitive element which stores a bit of information as an amount of charge on the capacitive element.

The selection of the word line WL is performed by a row decoder 108 and the selection of the bit lines BL is performed by a column decoder 1010. In the embodiment of FIG. 10, the row decoder 1008 includes a respective row decoder for each memory bank and the column decoder 1010 includes a respective column decoder for each memory bank. The bit lines BL are coupled to a respective sense amplifier (SAMP). During an access operation, the row decoder 1008 activates the word line specified by a row address XADD. The memory cells MC along the active word line are coupled to the intersecting bit lines BL. The sense amplifiers SAMP amplifies the signal along the bit line, either to the memory cell in a write operation or from the memory cell in a read operation. The column decoder 1010 selects one or more bit lines to couple through local and global input output lines (LIO/GIO) outside the array 1018.

The semiconductor device 1000 may employ a plurality of external terminals. The external terminals include command and address (C/A) terminals along a command and address bus to receive commands and addresses. Other external terminals include clock terminals to receive clocks CK and/CK along a clock bus, data terminals DQ to send and receive data along a data bus, and power supply terminals to receive power supply potentials such as VDD, VSS, VDDQ, and VSSQ. The memory device 100 also includes data strobe (DQS) terminals which are used to receive a DQS signal. The DQS signal is used by an input/output (IO) circuit 1022 to clock data as it is being sent or received along the DQ terminals.

The clock terminals are supplied with external clocks CK and/CK that are provided to an input circuit 1012. The external clocks may be complementary. The input circuit 1012 generates an internal clock ICLK based on the CK and/CK clocks. The ICLK clock is provided to the command decoder 1010 and address decoder 1008 and to an internal clock generator 1014. The internal clock generator 1014 provides various internal clocks LCLK based on the ICLK clock. The LCLK clocks may be used for timing operation of various internal circuits. For example, the clock signal LCLK may be a divided clock signal which is half the frequency of the external clocks CK and/CK.

The C/A terminals may be supplied with memory addresses. The memory addresses supplied to the C/A terminals are transferred, via a command/address input circuit 1002, to an address decoder 1004. The address decoder 1004 receives the address and supplies a decoded row address XADD to the row decoder 1008 and supplies a decoded column address YADD to the column decoder 1010. The address decoder 1004 may also supply a decoded bank address BADD, which may indicate the bank of the memory array 1018 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 1006 via the command/address input circuit 1002. The command decoder 1006 includes circuits to decode the internal command signals to generate various internal signals and commands for performing operations. For example, the command decoder 106 may provide a read signal or a write signal to the column decoder 1010 responsive to a read or write command respectively. The read command may cause the data on the bit line(s) selected by the column decoder 1010 to be read out along the LIO/GIO lines. The write command may cause data to be written along the LIO/GIO lines to the selected bit line(s) and through them to the memory cells.

As part of an example write operation, the device 1000 may receive a write command along with memory addresses which indicate where the write command should be performed. The IO circuit 1022 receives data along the DQ terminals in synchronization with the DQS signal, and provides the data to the read/write amplifier circuits 1020. Responsive to internal commands (such as a row activate command ACT) issued by the command decoder 1006, the word line selected by XADD is activated by the row decoder 1008 and the data on the memory cells along that word line is amplified onto the intersecting bit lines by sense amplifiers (SAMP). Responsive to internal commands and the column address YADD, the column decoder 1010 couples selected bit lines through local and global input/output lines (LIO and GIO) to the read/write amplifiers 1020. The read/write amplifiers 1020 provide the data and error correction bits along the LIO/GIO to the selected bit lines where it is written to the memory cells at the intersections with the active word line.

As part of an example read operation, the device 1000 may receive a read command along with memory addresses which indicate where the read command should be performed. Responsive to internal commands (such as a row activate command ACT) issued by the command decoder 1006, the word line selected by XADD is activated by the row decoder 1008 and the data and error correction bits on the memory cells along that word line is amplified onto the intersecting bit lines by sense amplifiers (SAMP). Responsive to internal commands and the column address YADD, the column decoder 1010 couples selected bit lines through local and global input/output lines (LIO and GIO) to the read/write amplifiers 1020. The read/write amplifiers 1020 provide the corrected data to the IO circuit 1022, which provides the data along one or more DQ terminals. The corrected data may be provided in synchronization with a data strobe clock DQS.

During write operations, the IO circuit 1022 may generate internal signals to determine when to stop latching information being received along the DQ terminals. For example, responsive to a write command, the IO circuit 1022 receives data for a burst length, or a number of serial bits, along each of one or more DQ terminals. A command shifter of the IO circuit passes the write command through a number of flip-flop circuits based on the burst length. When the command exits the shifter it may be used to mark the end of write operations. A portion of an example command shifter is described in more detail in FIG. 11.

During read and write operations, data is sent and received on latches of the IO circuit 1022 with timing based on the strobe signal DQS. Internal operations in the memory device 1000 are generally controlled by the timing of a clock signal such as CK, one or more signals derived therefrom, such as ICLK and LCLK, or combinations therefrom. During write operations, it may be useful to ensure that the clock signal (e.g., LCLK) and the DQS signal are aligned with each other. During an external write leveling (EWL) operation, mock commands and data are sent along with the clock and DQS signals. EWL logic circuits 1023 of the IO circuit 1022 may compare the timing at which the mock data is received and set a delay to align the clock and DQS signal based on the measured timing. The EWL logic circuits 1023 may include one or more synchronizers, which may include one or more flip-flop circuits such as 100 of FIG. 1, 200a-g of FIGS. 2A-G, or combinations thereof. An example synchronizer is described in more detail in FIG. 12.

The device 1000 may also receive commands causing it to carry out refresh operations. A refresh control circuit 1016 may generate refresh address RXADD and the row decoder may refresh the word lines associated with that refresh address RXADD. The memory device 1000 may receive a refresh signal REF and perform one or more refresh operations responsive to the refresh signal. In some embodiments, the refresh control circuit 1016 may perform different types of refresh operations. For example, the refresh control circuit 1016 may perform ‘normal’ refresh operations where the refresh address RXADD is generated using sequence logic, for example to count through the row addresses or the refresh control circuit 1016 may perform targeted refresh operations on specific addresses (e.g., the victims of an identified aggressor).

The power supply terminals are supplied with power supply potentials VDD and VSS. The power supply potentials VDD and VSS are supplied to an internal voltage generator circuit 1024. The internal voltage generator circuit 1024 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 1022. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 1022 so that power supply noise generated by the input/output circuit 1022 does not propagate to the other circuit blocks.

FIG. 11 is a schematic diagram of a command shifter according to some embodiments of the present disclosure. The command shifter 1100 of FIG. 11 may, in some embodiments, be part of an IO circuit such as the IO circuit 1022 of FIG. 10. The view of the command shifter 1100 may represent a portion of a command shifter used in write operations. Specifically, the command shifter 1100 may represent an end of the command shifter, where the write command exits and generates a write end signal WrEndM2 to indicate that no more data will be received as part of this write operation. The view of the command shifter 1100 includes three flip-flop circuits 1102-1106. Additional flip-flip circuits may be part of the command shifter although they are not shown in FIG. 11.

Each of the flip-flop circuits 1102-1106 may be implemented by one of the flip-flop circuits 100 of FIG. 1, 200a-g of FIG. 2, or combinations thereof. In an example embodiment, the flip-flop 1102 may be implemented by the flip-flop 200c of FIG. 2C, the flip-flops 1104 may be implemented by the flip-flop circuit 200b of FIG. 2B, and the flip-flop 1106 may be implemented by the flip-flop 200d of FIG. 2D. In some embodiments, the flip-flops 1102-1106 may each include the first latch 400a of FIG. 4A, the NAND gate 500a of FIG. 5A, and the second latch 600a of FIG. 6A. Other arrangements of components may be used in other example embodiments.

Three flip-flop circuits 1102-1106 are shown in portion of the command shifter 1100. The flip-flops 1102-1106 are coupled in series, with the input terminal D of a flip-flop coupled to the output terminal Q of a previous flip-flop circuit. For example, the output Q of flip-flop 1102 is coupled to the input of flip-flop 1104, and the output Q of the flip-flop 1104 is coupled, through logic circuits 1108-114 to the input D of the flip-flop 1106. Each of the flip-flops 1102-1106 has a clock terminal CLK coupled in common to a clock signal DScntClk.

The first flip-flop circuit 1102 is an optional flip-flop circuit which is enabled or disabled depending on if an optional error correction bit CRC is part of the write data. The first flip-flop 1102 is a multiplexer flip-flop which has two inputs D and D2 and a multiplexer select terminal Mux2f coupled to a CRC enable signal mrWrCRCEn. The first input is coupled to a previous flip-flop circuit in the series, while the second input is coupled to the flip-flop previous to that. In this manner, when the enable signal mrWrCRCEn is inactive, a flip-flop may be skipped.

The second flip-flop 1104 provides an output through an inverter circuit 1108 to an input of a NAND gate 1114. The other inputs of the NAND gate 1114 are coupled through NAND gates 1110 and 1112 to various command signals used to control the operation of the command shifter 1100. The output of the NAND gate 1114 is provided to the input of the flip-flop 1106. The output of the third flip-flop 1106 is the write stop signal WrEndM2. The signal WrEndM2 is also passed through two inverter circuits 1116 and 1118 in series to generate a buffered signal WrEndM2b. The buffered write end signal WrEndM2b is provided to the reset terminal R It of the second flip-flop 1104.

FIG. 12 is a schematic diagram of a synchronizer circuit according to some embodiments of the present disclosure. The synchronizer circuit 1200 may be part of an external write leveling (EWL) logic circuit, such as 1023 of FIG. 10. The synchronizer circuit 1200 shows a pair of flip-flops analogous to the flip-flop circuit 100 of FIG. 1. The flip-flops are split such that they share a first latch 1202 (e.g., 102 of FIG. 1), but have separate second latch portions 1210 and 1220 each of which includes a respective NAND gate and second latch. For example, the second latch portion 1210 includes NAND gate 1212 and latch 1214 and the second latch portion 1220 includes NAND gate 1222 and latch 1224.

In some example embodiments, the latch 1202 may be implemented by the gated extend circuit 400b of FIG. 4B, the NAND gates 1212 and 1222 may be implemented by the NAND gate 500b of FIG. 5B, and the latches 1214 and 1224 may be implemented by the latch 600b of FIG. 6B. In some embodiments, the latch 1202 may be a different type of latch, such as a gated extend circuit, than the latches 1214 and 1224. In some embodiments, the latches 1214 and 1224 may be a same type of latch as each other.

The synchronizer 1200 receives a reset signal RF, a write leveling write command WL_WrCmd, and a write leveling write clock WL_WrClk. The write leveling command and clock WL_WrCmd and WL_WrClk may be provided as part of the EWL operation. The first latch 1202 has an input terminal D coupled to WL_WrCmd, an enable terminal CLK coupled to WL_WrClk and a reset terminal Rt coupled through inverter circuit 1204 to the reset signal RF. An output Y of the first latch 1202 is coupled to the first latch portion 1210. Because the two latch portions 1210 and 1220 may generally be similar to each other, only the first latch portion 1210 is described in detail.

The latch portion 1210 includes a first data input D, a second data input D2, an enable terminal LAT, a clock terminal CLK and an output terminal Q. The first latch portion 1210 includes a NAND gate 1212 with input terminals coupled to CLK and D. The output of the NAND gate 1212 is coupled to a set terminal Sf of a latch 1214. The latch 1214 also has an input terminal D coupled to the D2 terminal of the portion and an enable terminal LAT coupled to the LAT terminal of the portion.

The first portion 1210 has a data input coupled to the output of the first latch 1202, a clock terminal coupled to WL_WrClk, a latch terminal LAT coupled to RF, and a second data input D2 coupled to a ground voltage. The second portion 1220 has its data terminal and latch terminal coupled to RF, its clock terminal coupled the output of the first latch portion 1210, and its second data input coupled to a ground voltage. The output of the second portion 1220 is a write level command capture signal WL_WrCmdCapture.

During an example write level operation, the reset signal RF may be inactive at a high logical level. When the write level clock WL_WrClk falls to a low logical level, the value of the write level command WL_WrCmd is captured in the first latch 1202, which begins providing that value as the output Y. For the sake of this example operation, we will assume the latched value is a logical high. Responsive to the output of the first latch 1202 becoming high, the NAND gate 1212 provides a logical low when the clock signal WL_WrClk becomes high. The NAND gate 1212 providing a logical low causes the latch 1214 to become set. In this way the output of the latch 1214 (and portion 1210) becomes a logical high on the next rising edge of the clock WL_WrClk after WL_WrCmd became a logical high. Since the reset signal RF is a logical high, when the output of the latch portion 1210 becomes a logical high, the NAND gate 1222 of the second portion 1220 provides a logical low. This sets the latch 1224 and causes it to provide a logical high as the output WL_WrCmdCapture.

The output WL_WrCmdCapture will remain a logical high until the reset signal RF becomes active and changes to a logical low. When the reset signal RF becomes a logical low, the latch 1202 is reset. The latches 1214 and 1224 are both enabled to latch their input values, which is a ground voltage that represents a logical low.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a reset terminal;
a clock terminal;
a data terminal;
an output terminal;
a first latch circuit comprising an input terminal coupled to the data terminal, an enable terminal coupled to the clock terminal;
a NAND gate with a first input coupled to the clock terminal and a second input coupled to an output of the first latch; and
a second latch circuit comprising an input, an enable terminal coupled to the reset terminal, and a set terminal coupled to an output of the NAND gate, wherein an output of the second latch circuit is coupled to the output terminal.

2. The apparatus of claim 1, wherein the first latch circuit comprises a first latch reset terminal coupled to the reset terminal, and
wherein the second latch circuit has an input terminal coupled to a ground voltage.

3. The apparatus of claim 1, further comprising:
an inverter circuit coupled to the output of the second latch circuit; and
a second NAND gate with a first input coupled to the reset terminal and a second input coupled to an output of the inverter circuit.

4. The apparatus of claim 3, further comprising:
a second reset terminal;
a second inverter circuit with an input coupled to the reset terminal; and
a NOR gate with a first input coupled to the second reset terminal and a second input coupled to an output of the second inverter circuit, wherein an output of the NOR gate is coupled to the enable terminal of the second latch circuit.

5. The apparatus of claim 3, further comprising:
a multiplexer signal terminal;
a second data terminal;
a second reset terminal;
a third NAND gate with a first input coupled to the multiplexer signal terminal and a second input terminal coupled to the reset terminal; and
a NOR gate with a first input terminal coupled to the second input terminal and a second input coupled to an output of the third NAND gate,
wherein the second latch circuit has an input coupled to the second data terminal and the enable terminal is coupled to the output of the NOR gate.

6. The apparatus of claim 3, further comprising a second reset terminal, wherein an enable terminal of the second latch circuit is coupled to the second reset terminal.

7. The apparatus of claim 1, further comprising:
a set terminal;
a set signal generator circuit configured to generate an inverse set signal and an extended set signal from the set signal on the set terminal;
an inverter circuit coupled to the output of the second latch circuit;
a second NAND gate with a first input coupled to the set terminal and a second input coupled to an output of the inverter circuit; and
a NOR gate with a first input coupled to the reset terminal, a second terminal coupled to the inverse set signal, and an output coupled to the enable terminal of the second latch circuit,
wherein an input of the second latch circuit is coupled to the extended set signal.

8. The apparatus of claim 1, wherein the first latch circuit is a gated extend circuit.

9. The apparatus of claim 1, wherein the NAND gate comprises:
a first transistor configured to couple a system voltage to the output if the second input is a logical low; and
a second transistor configured to couple the system voltage to the output if the first input is a logical low.

10. The apparatus of claim 9, further comprising:
a switch configured to be activated by a control signal; and
a third transistor configured to enable the first transistor when the switch is activated.

11. The apparatus of claim 9, wherein the first transistor is smaller than the second transistor.

12. The apparatus of claim 1, wherein the second latch comprises:
a first inverter circuit coupled to the input of the second latch circuit;
a second NAND gate with an input coupled to an output of the first inverter circuit and an input coupled to the set terminal;
a second inverter circuit coupled between an output of the second NAND gate and the output of the first inverter circuit; and
a buffer circuit coupled between the output of the second NAND gate and the output of the second latch circuit.

13. An apparatus comprising:
a flip-flop circuit comprising a data terminal, a clock terminal configured to receive a clock signal, a first latch circuit, a NAND gate, and a second latch circuit, wherein responsive to the data terminal receiving a logical high and the clock signal being a logical low the first latch circuit is configured to latch the data and provide a logical low,
wherein the NAND gate is configured to provide a logical low to a set terminal of the second latch circuit responsive to the first latch circuit providing a logical high and the clock being a logical high, and
wherein the second latch circuit is configured to set an output value of the flip-flop circuit to a logical high responsive to the NAND gate providing a logical low.

14. The apparatus of claim 13, wherein the flip-flop circuit further comprises a reset terminal configured to receive a reset signal, wherein the second latch circuit is configured to latch an input value which represents a logical low responsive to the reset signal being active.

15. The apparatus of claim 13, wherein the flip-flop circuit wherein first latch circuit is reset to a logical low responsive to the output of the flip-flop circuit becoming a logical high.

16. The apparatus of claim 13, wherein responsive to the data terminal receiving a logical low after receiving the logical high while the clock signal is a logical low, the first latch circuit is configured to still provide the logical low for a delay time after the data terminal begins receiving the logical low.

17. A memory device comprising:
a first latch circuit with an input terminal coupled to a command signal, a clock terminal coupled to a clock signal, a reset terminal coupled to a reset signal, and an output;
a first latch portion comprising:
a first NAND gate with a first input terminal coupled to the clock signal and a second input terminal coupled to the output of the first latch circuit; and
a second latch circuit with an input coupled to a ground voltage, an enable terminal coupled to the reset signal, and a set terminal coupled to an output of the first NAND gate; and
a second latch portion comprising:
a second NAND gate with a first input terminal coupled to an output of the second latch circuit and a second input terminal coupled to the reset signal; and
a third latch circuit with an input coupled to a ground voltage, an enable terminal coupled to the reset signal, and a set terminal coupled to an output of the second NAND gate.

18. The memory device of claim 17, wherein the first latch circuit, first latch portion and second latch portion are part of an external write leveling synchronizer circuit,
wherein the clock signal is a write leveling clock signal,
wherein the command signal is a write leveling command signal, and
wherein an output of the third latch circuit is a write leveling write command capture signal.

19. The memory device of claim 17, wherein the first latch circuit is a gated extend circuit.

20. The memory device of claim 19, wherein the second latch circuit and the third latch circuit are a different type of latch than the first latch circuit.
